(19) United States
(12) Patent Application Publication
(10) Pub. No.: US 2026/0180043 A1
(43) Pub. Date: Jun. 25, 2026

(54) CIRCUIT BOARD AND BATTERY PACK

(71) Applicant: MURATA MANUFACTURING CO., LTD., Kyoto (JP)

(72) Inventor: Hideyasu TAKATSUJI, Kyoto (JP)

(21) Appl. No.: 19/316,530

(22) Filed: Sep. 2, 2025

(30) Foreign Application Priority Data
Oct. 18, 2024 (JP) 2024-184364

(51) Int. Cl. H01M 10/42; H01M 50/213; H05K 1/18

(52) U.S. Cl. CPC H01M 10/425; H01M 50/213; H05K 1/181; H05K 2201/10522

(57) ABSTRACT

A circuit board includes a wiring substrate, electronic components, and a resin part. The resin part includes a first resin part covering a surface of a first component and a second resin part covering a surface of a second component. t1 to t4 satisfy the following Expressions (1) to (4),

t1>t3 (1)

t1>t4 (2)

t2>t3 (3)

t2>t4 (4)

where t1 is a maximum thickness of a part of the first resin part covering a first component top surface, t2 is a maximum thickness of a part of the first resin part covering a first component side surface, t3 is a maximum thickness of a part of the second resin part covering a second component top surface, and t4 is a maximum thickness of a part of the second resin part covering a second component side surface.

### CROSS-REFERENCE TO RELATED APPLICATIONS

The present application claims priority from Japanese Patent Application No. 2024-184364 filed on Oct. 18, 2024, the entire contents of which are hereby incorporated by reference.

### BACKGROUND

The present disclosure relates to a circuit board and a battery pack.

A battery pack is provided with a circuit board that controls charging and discharging of a plurality of batteries in the battery pack.

### SUMMARY

The present disclosure relates to a circuit board and a battery pack.

A circuit board according to an embodiment of the present disclosure includes a wiring substrate, a plurality of electronic components, and a resin part. The wiring substrate includes a major surface. The plurality of electronic components is mounted on the major surface. The resin part covers the plurality of electronic components. The plurality of electronic components includes a first component mainly including resin and a second component mainly including metal. The resin part includes one kind of resin material.

The resin part includes a first resin part covering a surface of the first component and a second resin part covering a surface of the second component. t1 to t4 satisfy the following Expressions (1) to (4),

t1>t3 (1)

t1>t4 (2)

t2>t3 (3)

t2>t4 (4)

where t1 is a maximum thickness of a part of the first resin part covering a top surface of the first component, t2 is a maximum thickness of a part of the first resin part covering a side surface of the first component, t3 is a maximum thickness of a part of the second resin part covering a top surface of the second component, and t4 is a maximum thickness of a part of the second resin part covering a side surface of the second component.

A battery pack according to an embodiment of the present disclosure includes one or more batteries and a circuit board. The circuit board is configured to control charging and discharging of the one or more batteries. The circuit board includes a wiring substrate, a plurality of electronic components, and a resin part. The wiring substrate includes a major surface. The plurality of electronic components is mounted on the major surface. The resin part covers the plurality of electronic components. The plurality of electronic components includes a first component mainly including resin and a second component mainly including metal. The resin part includes one kind of resin material. The resin part includes a first resin part covering a surface of the first component and a second resin part covering a surface of the second component. t1 to t4 satisfy the following Expressions (1) to (4),

t1>t3 (1)

t1>t4 (2)

t2>t3 (3)

t2>t4 (4)

where t1 is a maximum thickness of a part of the first resin part covering a top surface of the first component, t2 is a maximum thickness of a part of the first resin part covering a side surface of the first component, t3 is a maximum thickness of a part of the second resin part covering a top surface of the second component, and t4 is a maximum thickness of a part of the second resin part covering a side surface of the second component.

### BRIEF DESCRIPTION OF THE FIGURES

The accompanying drawings are included to provide a further understanding of the present disclosure and are incorporated in and constitute a part of this specification. The drawings illustrate example embodiments and, together with the specification, serve to explain the principles of the present disclosure.

FIG. 1 is a diagram illustrating a planar configuration example of a circuit board according to one example embodiment of the present disclosure.

FIG. 2 is a diagram illustrating a planar configuration example of a wiring substrate of FIG. 1.

Part (A) of FIG. 3 is a diagram illustrating a sectional configuration example of the circuit board of FIG. 1 taken along line A-A, and part (B) of FIG. 3 is a diagram illustrating a planar configuration example of a part, including line A-A, of the circuit board of FIG. 1.

FIG. 4 is a diagram illustrating, in an enlarged manner, the sectional configuration example illustrated in part (A) of FIG. 3.

FIGS. 5A to 5C are diagrams describing a design concept of a thickness of a resin part of FIG. 1.

FIG. 6 is a graph illustrating an example of a simulation result of a relationship between a thickness of a mold resin and a component deformation amount when an ambient temperature of the circuit board in which a resin component and a metal component are covered with the mold resin is changed from −40° C. to +85° C.

FIG. 7A is a diagram illustrating a sectional configuration example of the circuit board of FIG. 1 taken along line A-A when the circuit board of FIG. 1 is placed in an ambient temperature of −40° C.

FIG. 7B is a diagram illustrating a sectional configuration example of the circuit board of FIG. 1 taken along line A-A when the ambient temperature of the circuit board of FIG. 1 is changed from −40° C. to +85° C.

FIG. 8A is a diagram illustrating a sectional configuration example of a circuit board according to a comparative example when the circuit board according to the comparative example is placed in an ambient temperature of −40° C.

FIG. 8B is a diagram illustrating a sectional configuration example of the circuit board according to the comparative example when the ambient temperature of the circuit board of FIG. 8A is changed from −40° C. to +85° C.

FIG. 9A is a diagram illustrating a planar configuration example of a lower mold.

FIG. 9B is a diagram illustrating a sectional configuration example of the lower mold of FIG. 9A taken along line A-A.

FIG. 10A is a diagram illustrating a planar configuration example of an upper mold.

FIG. 10B is a diagram illustrating a sectional configuration example of the upper mold of FIG. 10A taken along line A-A.

FIG. 11 is a flowchart illustrating an example of a manufacturing procedure of the circuit board of FIG. 1.

FIG. 12 is a diagram illustrating one modification example of the planar configuration example of the circuit board of FIG. 1.

FIG. 13 is a diagram illustrating one modification example of a perspective configuration example of a first resin part illustrated in part (B) of FIG. 3.

FIG. 14 is a diagram illustrating a sectional configuration example of the first resin part of FIG. 13 taken along line A-A.

FIG. 15 is a diagram illustrating one modification example of the sectional configuration example of the circuit board of FIG. 1 taken along line A-A.

FIG. 16 is a diagram illustrating a perspective configuration example of the first resin part of FIG. 15.

FIG. 17 is a diagram illustrating one modification example of the sectional configuration example of the circuit board of FIG. 1 taken along line A-A.

FIG. 18 is a diagram illustrating one modification example of the sectional configuration example of the circuit board of FIG. 1 taken along line A-A.

FIG. 19 is a diagram illustrating a perspective configuration example of a battery pack.

FIG. 20 is a diagram illustrating a perspective configuration example of a battery module that is one of contents of the battery pack of FIG. 19.

FIG. 21 is a diagram illustrating an exploded perspective configuration example of the battery pack of FIG. 19.

### DETAILED DESCRIPTION

An electronic component such as an integrated circuit (IC) mounted on a circuit board may be covered with a waterproof resin in order to prevent deterioration due to moisture contained in an outside air and water exposure. Such a waterproof resin is formed by, for example, in a manufacturing process, sandwiching the circuit board with molds, plasticizing a solid resin pellet in a melting furnace and converting the solid resin pellet into liquid, injecting the liquid resin into the molds from a gate, and curing the liquid resin in the molds by cooling. In a case where the waterproof resin is formed by such mold forming, a linear expansion coefficient of the electronic component covered with the molded waterproof resin may be very large compared with a linear expansion coefficient of the waterproof resin. In this case, upon expansion and contraction of the electronic component by, for example, thermal cycling, stress concentration may occur on the waterproof resin covering the expanded and contracted electronic component and at the interface between the expanded and contracted electronic component and the waterproof resin. The stress concentration may possibly cause the waterproof resin to, for example, peel off from the circuit board, thus causing a failure in waterproofing by the waterproof resin.

It is desirable to provide a circuit board and a battery pack that each make it possible to prevent a failure in waterproofing by a waterproof resin.

In the following, one or more example embodiments of the present disclosure are described in detail with reference to the accompanying drawings. Note that the following description is directed to illustrative examples of the present disclosure and not to be construed as limiting to the present disclosure. Factors including, without limitation, numerical values, shapes, materials, components, positions of the components, and how the components are coupled to each other are illustrative only and not to be construed as limiting to the present disclosure. Further, elements in the following example embodiments which are not recited in a most-generic independent claim of the present disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the present disclosure are unillustrated in the drawings.

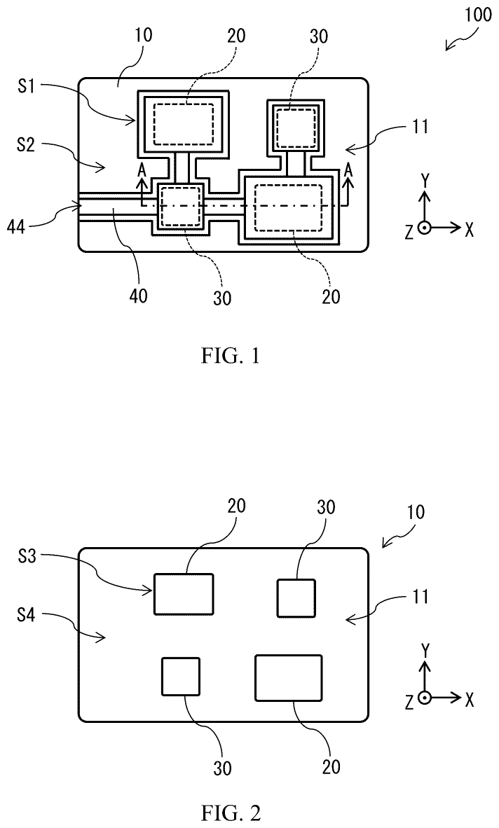

First, a circuit board 100 according to an example embodiment of the present disclosure will be described. FIG. 1 illustrates a planar configuration example of the circuit board 100. As illustrated in FIG. 1, the circuit board 100 includes a wiring substrate 10 including a major surface 11. The circuit board 100 further includes a plurality of electronic components mounted on the major surface 11.

The plurality of electronic components mounted on the major surface 11 may include at least one kind of components selected out of, for example but not limited to, a microcontroller, an integrated circuit (IC), a fuse, an energizing busbar, a resistor, and a capacitor. In the example embodiment, as the plurality of electronic components, at least two kinds of components selected out of, for example but not limited to, a microcontroller, an IC, a fuse, an energization busbar, a resistor, and a capacitor may be mounted on the major surface 11. The wiring substrate 10 may correspond to a specific but non-limiting example of a “wiring substrate” in an embodiment of the present disclosure.

As illustrated in FIG. 1, the circuit board 100 may include a plurality of resin components 20 and a plurality of metal components 30 as the plurality of electronic components mounted on the major surface 11. Each of the resin components 20 is an electronic component mainly including resin. In each of the resin components 20, a volume occupancy ratio of a resin material may be higher than a volume occupancy ratio of other one or more materials. Each of the resin components 20 may be, for example, an electronic component in which a package material includes a resin material. Each of the metal components 30 is an electronic component mainly including metal. In each of the metal components 30, a volume occupancy ratio of a metal material may be higher than a volume occupancy ratio of other one or more materials. Each of the metal components 30 may be, for example, an electronic component in which an outermost surface includes a metal material. Each of the resin components 20 may correspond to a specific but non-limiting example of a “first component” in an embodiment of the present disclosure. Each of the metal components 30 may correspond to a specific but non-limiting example of a “second component” in an embodiment of the present disclosure.

The circuit board 100 may further include, as illustrated in FIG. 1, a resin part 40 provided to be in contact with only a part of the major surface 11, but not the entire major surface 11. The resin part 40 in contact with the major surface 11 may correspond to a specific but non-limiting example of a “resin part” in an embodiment of the present disclosure. The resin part 40 covers the above-described plurality of electronic components (for example, the plurality of resin components 20 and the plurality of metal components 30). The resin part 40 may be a single, continuous structure. The resin part 40 may include a waterproof resin material that helps to protect the above-described plurality of electronic components from, for example but not limited to, moisture in the atmosphere or submersion of the circuit board 100. The resin part 40 includes one kind of resin material. In an embodiment, the resin part 40 may include one kind of resin selected from the group consisting of, for example, polyamide, polyester, and polyurethane.

The wiring substrate 10 may be a plate-shaped component including an insulating substrate on which an electrically conductive metal is provided as a wiring. The wiring substrate 10 may be a printed wiring board (PWB) without the plurality of electronic components described above. In an embodiment, the wiring substrate 10 may be a plate-shaped component in which a wiring is provided on a surface of a single insulating substrate. In an embodiment, the wiring substrate 10 may be a plate-shaped component in which a wiring is provided on a surface of and inside a stacked body. The stacked body may include a plurality of insulating substrates stacked on one another. The major surface 11 of the wiring substrate 10 may include a covered region S1 that is a single, continuous region covered with the resin part 40, and an uncovered region S2 that is not covered with the resin part 40. As illustrated in FIG. 2, the major surface 11 of the wiring substrate 10 may include a plurality of mounting regions S3 each mounting one of the plurality of electronic components described above, and a non-mounting region S4 on which the plurality of electronic components described above is not mounted. FIG. 2 illustrates a planar configuration example of the major surface 11 of the wiring substrate 10.

The plurality of mounting regions S3 may each be provided with a pad electrode adapted to electrically couple the corresponding electronic component and the wiring of the wiring substrate 10 described above. The non-mounting region S4 may include no pad electrodes described above, and the surface of the insulating substrate or a thin film covering the surface of the insulating substrate may be exposed. The resin part 40 may extend from a gate part 44 in contact with an edge of the wiring substrate 10 and over the plurality of mounting regions S3 and parts of the non-mounting region S4 in plan view.

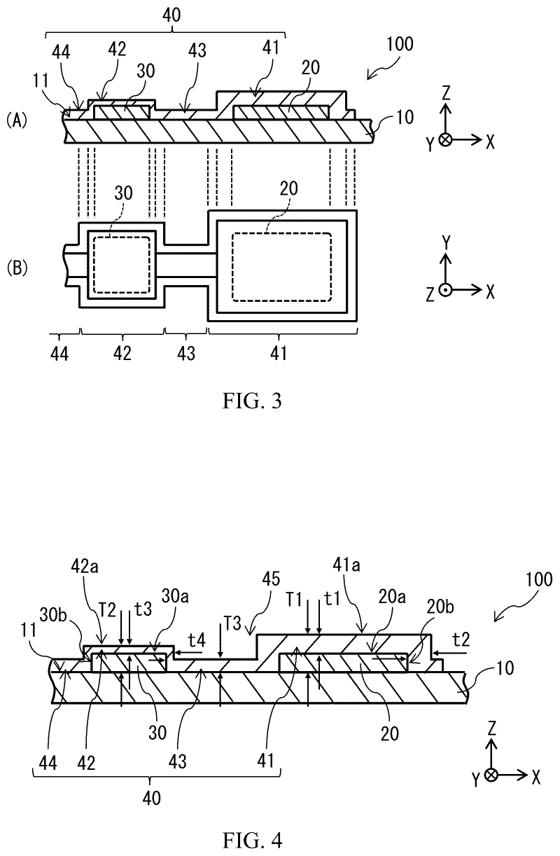

Part (A) of FIG. 3 illustrates a sectional configuration example of the circuit board 100 of FIG. 1 taken along line A-A. Part (B) of FIG. 3 illustrates a planar configuration example of a part, including line A-A, of the circuit board 100 of FIG. 1. FIG. 4 illustrates the sectional configuration example illustrated in part (A) of FIG. 3 in an enlarged manner. The resin part 40 may be a resin mold formed by low-pressure molding using a mold. The resin part 40 may have a three-dimensional shape corresponding to the shape of a recess 221 of an upper mold 220 to be described later. Herein, the “low-pressure molding” may refer to molding under conditions of 90° C. to 240° C. and 3 kgf/cm² to 50 kgf/cm².

In the following, for simplicity of description, one of the plurality of resin components 20 and one of the plurality of metal components 30 will be described. However, the following description applies to any of the plurality of resin components 20 and any of the plurality of metal components 30 described above. The resin part 40 includes a first resin part 41 that covers a surface of the resin component 20 and a second resin part 42 that covers a surface of the metal component 30. The first resin part 41 may be in contact with a top surface 20a and a side surface 20b of the resin component 20 and may also be in contact with the major surface 11 (the non-mounting region S4) of the wiring substrate 10. The second resin part 42 may be in contact with a top surface 30a and a side surface 30b of the metal component 30 and may also be in contact with the major surface 11 (the non-mounting region S4) of the wiring substrate 10. In an embodiment, the resin part 40 may further include a third resin part 43 provided between the first resin part 41 and the second resin part 42. In an embodiment, the third resin part 43 may couple the first resin part 41 and the second resin part 42. The third resin part 43 may be in contact with the major surface 11 (the non-mounting region S4) of the wiring substrate 10.

A maximum thickness of a part of the first resin part 41 covering the top surface 20a of the resin component 20 may be represented by t1. The maximum thickness t1 may correspond to a maximum thickness of the first resin part 41 from the top surface 20a of the resin component 20 to part of an outer surface 41a of the first resin part 41 opposed to the top surface 20a of the resin component 20. A maximum thickness of a part of the first resin part 41 covering the side surface 20b of the resin component 20 may be represented by t2. The maximum thickness t2 may correspond to the maximum thickness of the first resin part 41 from the side surface 20b of the resin component 20 to part of the outer surface 41a of the first resin part 41 opposed to the side surface 20b of the resin component 20. A maximum thickness of a part of the second resin part 42 covering the top surface 30a of the metal component 30 may be represented by t3. The maximum thickness t3 may correspond to the maximum thickness of the second resin part 42 from the top surface 30a of the metal component 30 to part of an outer surface 42a of the second resin part 42 opposed to the top surface 30a of the metal component 30. A maximum thickness of a part of the second resin part 42 covering the side surface 30b of the metal component 30 may be represented by t4. The maximum thickness t4 may correspond to the maximum thickness of the second resin part 42 from the side surface 30b of the metal component 30 to part of the outer surface 42a of the second resin part 42 opposed to the side surface 30b of the metal component 30. In this case, the maximum thicknesses t1 to t4 satisfy the following Expressions (1) to (4). When the maximum thicknesses t1 to t4 satisfy the following Expressions (1) to (4), the thickness of the first resin part 41 covering the resin component 20 is larger than the thickness of the second resin part 42 covering the metal component 30. The technical basis of the thickness of the first resin part 41 covering the resin component 20 and the thickness of the second resin part 42 covering the metal component 30 will be described in detail later.

t1>t3 (1)

t1>t4 (2)

t2>t3 (3)

t2>t4 (4)

Herein, the term “opposed to” may be a concept including not only a case where the outer surface of the resin part 40 is directly opposed to the top surface of the electronic component (the resin component 20 or the metal component 30), but also a case where the outer surface of the resin part 40 is opposed to the top surface of the electronic component (the resin component 20 or the metal component 30) obliquely with respect to a normal direction (a height direction) of the top surface. Herein, the term “opposed to” may be a concept including not only a case where the outer surface of the resin part 40 is directly opposed to the side surface of the electronic component (the resin component 20 or the metal component 30), but also a case where the outer surface of the resin part 40 is opposed to the side surface of the electronic component (the resin component 20 or the metal component 30) obliquely with respect to a normal direction (a lateral direction) of the side surface of the electronic component (the resin component 20 or the metal component 30).

The maximum height of the first resin part 41 from the major surface 11 may be represented by T1. The maximum height of the second resin part 42 from the major surface 11 may be represented by T2. The maximum height of the third resin part 43 from the major surface 11 may be represented by T3. In an embodiment, the maximum heights T1 to T3 may satisfy the following Expressions (5) and (6). When the maximum heights T1 to T3 satisfy the following Expressions (5) and (6), a grooved part 45 may be provided in the resin part 40. In an embodiment, the grooved part 45 may include an inner wall and a bottom surface. The inner wall may include a part of a surface of a region, in the outer surface 41a of the first resin part 41, covering the side surface 20b of the resin component 20 and a part of a surface of a region, in the outer surface 42a of the second resin part 42, covering the side surface 30b of the metal component 30. The bottom surface may include the surface of the third resin part 43. In an embodiment, the maximum height T3 may correspond to the height from the major surface 11 to the bottom surface of the grooved part 45 and satisfy the following Expression (7).

T3<T1 (5)

T3<T2 (6)

T3<t1 (7)

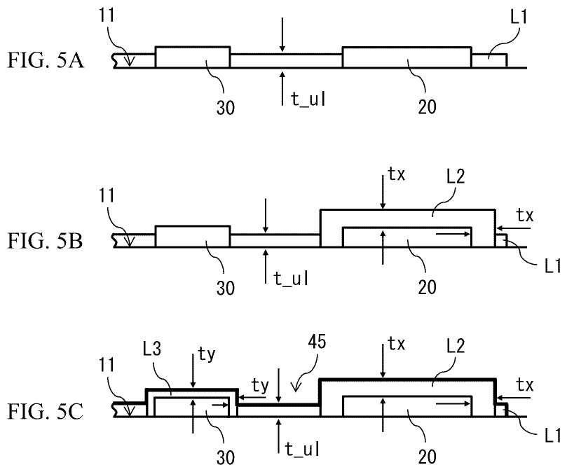

FIGS. 5A, 5B, and 5C describe a design concept of the thickness of the resin part 40. For example, as illustrated in FIG. 5A, the resin part 40 is to include at least a base layer L1 having a resin thickness defined by Underwriters Laboratories (UL) certification, which will be referred to as a UL-certified thickness t_ul. In this case, the presence of the resin component 20 and the metal component 30 does not necessarily have to be considered. The resin part 40 may further include a protective layer L2 covering the resin component 20, for example, as illustrated in FIG. 5B. The protective layer L2 may have a predetermined thickness tx. The thickness tx may be a thickness based on a magnitude of a linear expansion coefficient of the resin component 20. The resin part 40 may further include a protective layer L3 covering the metal component 30, for example, as illustrated in FIG. 5C. The protective layer L3 may have a predetermined thickness ty. The thickness ty may be a thickness based on a magnitude of a linear expansion coefficient of the metal component 30. Here, the linear expansion coefficient of the resin component 20 may be larger than the linear expansion coefficient of the metal component 30, and may be, for example, approximately four times the linear expansion coefficient of the metal component 30. Therefore, the thickness tx of the protective layer L2 may be approximately four times the thickness ty of the protective layer L3. The resin part 40 may be constituted by, for example, a layer in which the base layer L1, the protective layer L2, and the protective layer L3 are combined, as indicated by a thick line in FIG. 5C. As a result, the resin part 40 may be, for example, a layer having the grooved part 45 between the resin component 20 and the metal component 30 and having the maximum thicknesses t1 to t4.

The linear expansion coefficient of the resin part 40 may be smaller than the linear expansion coefficient of the resin component 20. Thus, when a temperature change occurs in a state in which the resin component 20 is not covered with the resin part 40, a displacement amount of the resin part 40 may be smaller than a displacement amount of the resin component 20. As a result, when a temperature change occurs in a state in which the resin component 20 is covered with the resin part 40, the displacement of the resin component 20 is suppressed by the resin part 40. In a case where the resin part 40 is also displaced in accordance with the displacement of the resin component 20, when a temperature is changed from a high temperature to a low temperature, the resin part 40 may maintain a shape at the high temperature, and a large cavity may possibly occur between the resin part 40 and the resin component 20. When such a cavity occurs, the thickness of a part of the resin part 40 covering the resin component 20 may remain thin, and the possibility that the resin part 40 is peeled off from the major surface 11 during repeated cooling and heating may become high. In a case where the displacement of the resin component 20 is suppressed by the resin part 40, the possibility that the cavity as described above occurs is low, and therefore, even if cooling and heating are repeated, the resin part 40 is not easily peeled off from the major surface 11.

In an embodiment, a difference between the linear expansion coefficient of the resin part 40 and the linear expansion coefficient of the resin component 20 may be larger than a difference between the linear expansion coefficient of the resin part 40 and the linear expansion coefficient of the metal component 30. This allows the displacement amount of the resin part 40 to be close to a displacement amount of the metal component 30 when a temperature change occurs in a state in which the metal component 30 is covered with the resin part 40. The displacement amount of the metal component 30 due to cooling and heating may be very small compared with that of the resin component 20. Therefore, even if the displacement amount of the resin part 40 is brought close to the displacement amount of the metal component 30, the possibility that the cavity as described above occurs is low. As a result, even if cooling and heating are repeated, the resin part 40 is not easily peeled off from the major surface 11.

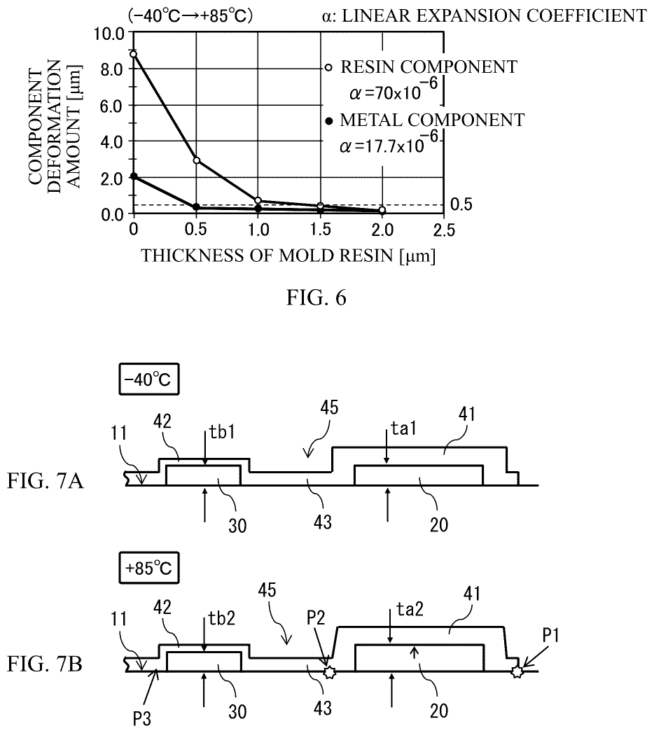

FIG. 6 illustrates an example of a simulation result of a relationship between a thickness of a mold resin and a component deformation amount when an ambient temperature of the circuit board in which the resin component 20 and the metal component 30 are covered with the mold resin is changed from −40° C. to +85° C. In this simulation, the linear expansion coefficient of the resin component 20 is 70.0×10⁻⁶/K, the linear expansion coefficient of the metal component 30 is 17.7×10⁻⁶/K, and a linear expansion coefficient of the mold resin is 26.0×10⁻⁶/K. FIGS. 7A and 7B illustrate a configuration example in this simulation. A thickness (ta2−ta1) obtainable by subtracting a thickness ta1 of the resin component 20 at −40° C. from a thickness ta2 of the resin component 20 at +85° C. corresponds to the component deformation amount in FIG. 6. Further, a thickness (tb2−tb1) obtainable by subtracting a thickness tb1 of the metal component 30 at −40° C. from a thickness tb2 of the metal component 30 at +85° C. corresponds to the component deformation amount in FIG. 6.

As can be appreciated from FIG. 6, when the resin component 20 and the metal component 30 are not covered with the mold resin (the thickness of the mold resin=0 μm), the resin component 20 deforms by 9.0 μm, and the metal component 30 deforms by 2.0 μm. When the resin component 20 and the metal component 30 are covered with the mold resin having a thickness of 0.5 μm, the resin component 20 deforms by 3.0 μm, and the metal component 30 deforms by 0.5 μm. Further, when the resin component 20 and the metal component 30 are covered with the mold resin having a thickness of 1.0 μm, the resin component 20 deforms by 0.8 μm, and the metal component 30 deforms by 0.4 μm. Further, when the resin component 20 and the metal component 30 are covered with the mold resin having a thickness of 1.5 μm, the resin component 20 deforms by 0.5 μm, and the metal component 30 deforms by 0.3 μm. Further, when the resin component 20 and the metal component 30 are covered with the mold resin having a thickness of 2.0 μm, the resin component 20 deforms by 0.2 μm, and the metal component 30 deforms by 0.2 μm.

When the ambient temperature is changed from −40° C. to +85° C., the resin part 40 (the mold resin) may possibly peel off at locations (relevant locations P1 and P2) where stress concentration is likely to occur, for example, as illustrated in FIG. 7B due to deformation of the resin component 20 and the metal component 30. However, if the deformation amount of the resin component 20 and the metal component 30 is suppressed to 0.5 μm or less, it is possible to prevent the resin part 40 (the mold resin) from peeling off from the wiring substrate 10 (the major surface 11) by an adhesion force of the resin part 40 (the mold resin) to the wiring substrate 10 (the major surface 11).

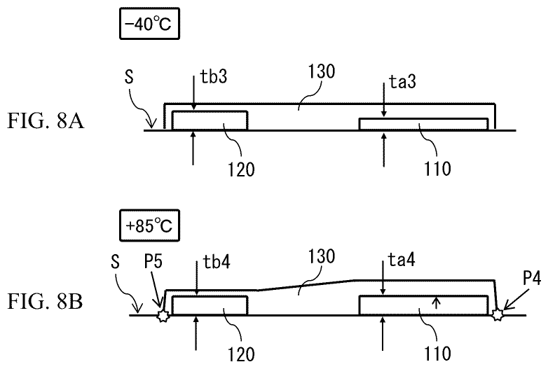

FIG. 8A illustrates a sectional configuration example of a circuit board according to a comparative example when the circuit board according to the comparative example is placed in an ambient temperature of −40° C. FIG. 8B illustrates a sectional configuration example of the circuit board according to the comparative example when the ambient temperature of the circuit board of FIG. 8A is changed from −40° C. to +85° C. In the circuit board according to the comparative example, as illustrated in FIGS. 8A and 8B, for example, a resin component 110 and a metal component 120 are mounted on a surface S, and the resin component 110 and the metal component 120 mounted on the surface S are covered with a resin layer 130. A thickness (ta4−ta3) obtainable by subtracting a thickness ta3 of the resin component 110 at −40° C. from a thickness ta4 of the resin component 110 at +85° C. corresponds to a component deformation amount of the resin component 110. Further, a thickness (tb4−tb3) obtainable by subtracting a thickness tb3 of the metal component 120 at −40° C. from a thickness tb4 of the metal component 120 at +85° C. corresponds to a component deformation amount of the metal component 120.

In the circuit board according to the comparative example, a thickness of the resin layer 130 is substantially uniform at −40° C., and the resin layer 130 is greatly raised by an expansion of the resin component 110 at +85° C. When the resin layer 130 is greatly raised due to the expansion of the resin component 110, stress concentration occurs at a relevant location P4. Further, the expansion of the resin component 110 pulls an end part (a relevant location P5) of the resin layer 130 closer to the metal component 120 toward the resin component 110, and thus stress concentration also occurs at the relevant location P5. As a result, the resin layer 130 may possibly peel off at the relevant locations P4 and P5.

When comparing FIG. 7B and FIG. 8B, it is evident that there is a difference in locations where stress concentration occurs. In FIG. 7B, in the first resin part 41 covering the resin component 20, stress concentration occurs at locations (the relevant locations P1 and P2) in the vicinity of the side surfaces of the resin component 20 that has expanded by a large amount. In FIG. 8B, stress concentration occurs at a location (the relevant location P5) of the resin layer 130 in the vicinity of a side surface of the metal component 120 in addition to the location (the relevant location P4) of the resin layer 130 in the vicinity of a side surface of the resin component 110. One reason for this is that the resin layer 130 does not include the grooved part 45 as illustrated in FIG. 7B, and the stress generated in the resin layer 130 is transferred to the vicinity (the relevant location P5) of the side surface of the metal component 120, and that the resin part 40 includes the grooved part 45 as illustrated in FIG. 7B, and thus the stress generated in the first resin part 41 does not reach the vicinity of the side surface of the metal component 30 owing to the occurrence of stress concentration in the grooved part 45. Note that, as illustrated in FIG. 7B, even if stress concentration occurs below the grooved part 45 (the relevant location P2) and peeling occurs below the grooved part 45 (the relevant location P2), there is less possibility that external water enters between the resin part 40 and the major surface 11.

A description is given next of a method of manufacturing the circuit board 100. First, molds (a lower mold 210 and the upper mold 220) to be used in the manufacturing process of the circuit board 100 will be described. Thereafter, a method of manufacturing the circuit board 100 using the molds (the lower mold 210 and the upper mold 220) will be described.

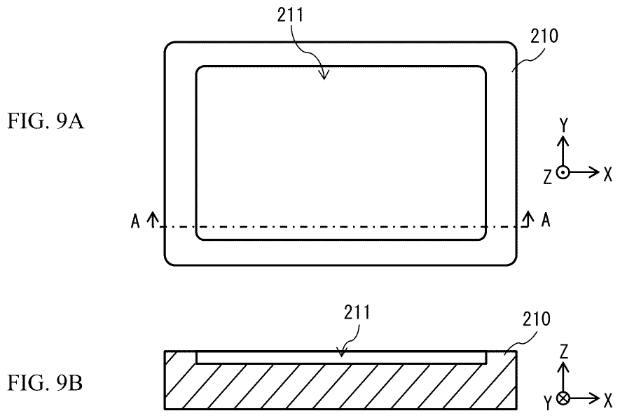

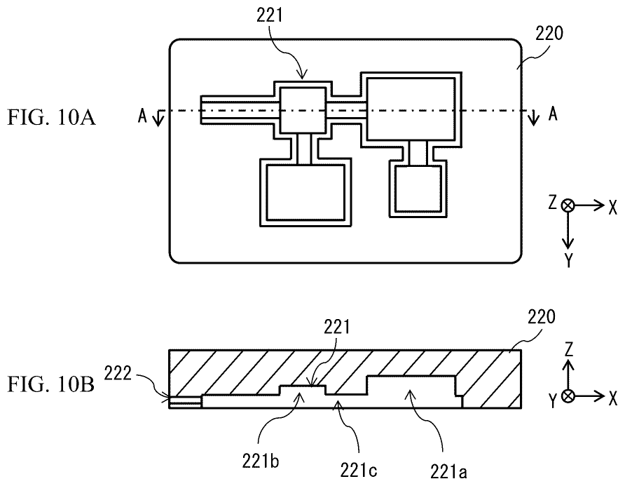

FIG. 9A illustrates a planar configuration example of the lower mold 210. FIG. 9B illustrates a sectional configuration example of the lower mold 210 of FIG. 9A taken along line A-A. FIG. 10A illustrates a planar configuration example of the upper mold 220. FIG. 10B illustrates a sectional configuration example of the upper mold 220 of FIG. 10A taken along line A-A.

The lower mold 210 may include, for example, as illustrated in FIGS. 9A and 9B, a receiving part 211 that receives the wiring substrate 10. The upper mold 220 may have the recess 221, for example, as illustrated in FIGS. 10A and 10B. When the upper mold 220 is stacked on the wiring substrate 10, the recess 221 may be opposed to a covering target region that is a single, continuous region, and may be a single, continuous structure. The covering target region may be a part of the major surface 11 and include the plurality of electronic components (the plurality of resin components 20 and the plurality of metal components 30).

The recess 221 may have a three-dimensional shape corresponding to the shape of the resin part 40. A gate part 222 may be coupled to one end of the recess 221. The gate part 222 may be a gap that couples the one end of the recess 221 to the outside, and serve as an inflow port that allows an uncured resin 200, which will be described later, to flow into the upper mold 220.

For example, as illustrated in FIG. 10B, the recess 221 may include three kinds of recesses 221a, 221b, and 221c having differing depths. The recess 221a may be a recess adapted to form the first resin part 41. The recess 221b may be adapted to form the second resin part 42. The recess 221c may be adapted to form the third resin part 43. The recess 221c may be provided between the recess 221a and the recess 221b.

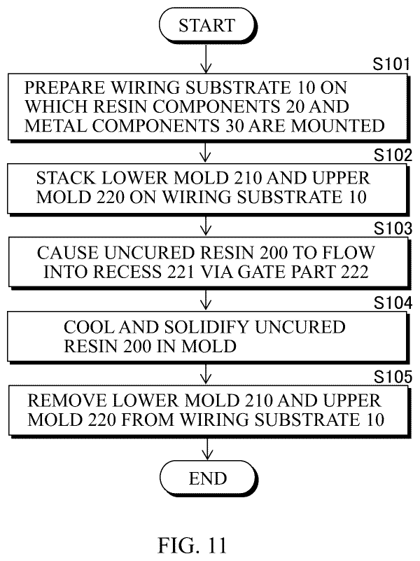

FIG. 11 illustrates an example of a manufacturing procedure of the circuit board 100. First, the wiring substrate 10 on which the plurality of electronic components (the plurality of resin components 20 and the plurality of metal components 30) are mounted may be prepared (step S101). Thereafter, the lower mold 210 and the upper mold 220 may be stacked on the wiring substrate 10 (step S102). Thereafter, the uncured resin 200 may be injected into the gate part 222 of the upper mold 220, thereby causing the uncured resin 200 to flow into the recess 221 via the gate part 222 (step S103). The uncured resin 200 may be a raw material of the resin part 40 and include one kind of thermoplastic resin material. In an embodiment, the uncured resin 200 may include, for example but not limited to, polyamide, polyester, or polyurethane.

Thereafter, the uncured resin 200 may be cooled in the molds (the lower mold 210 and the upper mold 220) and solidified (step S104). As a result, the resin part 40 may be formed. Thereafter, the molds (the lower mold 210 and the upper mold 220) may be removed from the wiring substrate 10. In this way, the circuit board 100 may be manufactured.

Next, example effects of the circuit board 100 will be described.

In the present example embodiment, the resin component 20 and the metal component 30 are covered with the resin part 40 including one kind of resin material. The thickness (the maximum thickness t1 and the maximum thickness t2) of the first resin part 41, of the resin part 40, covering the surface of the resin component 20 and the thickness (the maximum thickness t3 and the maximum thickness t4) of the second resin part 42, of the resin part 40, covering the surface of the metal component 30 satisfy the above Expressions (1) to (4). Thus, even in an environment in which the temperature difference is large, an expansion of the resin component 20 is suppressed by the first resin part 41. As a result, the adhesion force between the first resin part 41 and the wiring substrate 10 is maintained, and therefore, easy entry of water between the first resin part 41 and the wiring substrate 10 is prevented. This helps to prevent a failure in waterproofing by the resin part 40.

In an embodiment, the third resin part 43 may be provided between the first resin part 41 and the second resin part 42. The third resin part 43 may couple the first resin part 41 and the second resin part 42. The maximum height T1 of the first resin part 41, the maximum height T2 of the second resin part 42, and the maximum height T3 of the third resin part 43 may satisfy the above Expressions (5) and (6). In this case, the grooved part 45 may be provided in the resin part 40. The grooved part 45 may include the inner wall and the bottom surface. The inner wall may include a part of a surface of a region, in the outer surface 41a of the first resin part 41, covering the side surface 20b of the resin component 20 and a part of a surface of a region, in the outer surface 42a of the second resin part 42, covering the side surface 30b of the metal component 30. The bottom surface may include the surface of the third resin part 43. In an embodiment, the maximum height T3 may correspond to the height from the major surface 11 to the bottom surface of the grooved part 45 and satisfy the above Expression (7). Thus, the stress generated in the first resin part 41 by the expansion of the resin component 20 does not reach the vicinity of the side surface of the metal component 30 owing to the occurrence of the stress concentration in the grooved part 45. Further, as a depth of the grooved part 45 becomes deeper, the inner wall of the grooved part 45 easily extends in a depth direction of the grooved part 45. The extension of the inner wall of the grooved part 45 alleviates the stress generated in the first resin part 41 due to the expansion of the resin component 20. As a result, it is possible to reduce the possibility that peeling occurs in the resin part 40 (the second resin part 42) in the vicinity of the side surface of the metal component 30. This helps to prevent a failure in waterproofing by the resin part 40.

In an embodiment, the difference between the linear expansion coefficient of the resin part 40 and the linear expansion coefficient of the resin component 20 may be larger than the difference between the linear expansion coefficient of the resin part 40 and the linear expansion coefficient of the metal component 30. This allows the displacement amount of the resin part 40 to be close to the displacement amount of the metal component 30 when a temperature change occurs in the state in which the metal component 30 is covered with the resin part 40. The displacement amount of the metal component 30 due to cooling and heating may be very small compared with that of the resin component 20. Therefore, even if the displacement amount of the resin part 40 is brought close to the displacement amount of the metal component 30, the possibility that the cavity as described above occurs is low. As a result, even if cooling and heating are repeated, the resin part 40 is not easily peeled off from the major surface 11. This helps to prevent a failure in waterproofing by the resin part 40.

In an embodiment, the linear expansion coefficient of the resin part 40 may be smaller than the linear expansion coefficient of the resin component 20. Thus, when a temperature change occurs in the state in which the resin component 20 is not covered with the resin part 40, the displacement amount of the resin part 40 may be smaller than the displacement amount of the resin component 20. As a result, when a temperature change occurs in the state in which the resin component 20 is covered with the resin part 40, the displacement of the resin component 20 is suppressed by the resin part 40. In the case where the resin part 40 is also displaced in accordance with the displacement of the resin component 20, when a temperature is changed from a high temperature to a low temperature, the resin part 40 may maintain a shape at the high temperature, and a large cavity may possibly occur between the resin part 40 and the resin component 20. When such a cavity occurs, the thickness of a part of the resin part 40 covering the resin component 20 may remain thin, and the possibility that the resin part 40 is peeled off from the major surface 11 during repeated cooling and heating may become high. In the case where the displacement of the resin component 20 is suppressed by the resin part 40, the possibility that the cavity as described above occurs is low, and therefore, even if cooling and heating are repeated, the resin part 40 is not easily peeled off from the major surface 11. This helps to prevent a failure in waterproofing by the resin part 40.

Next, modification examples of the circuit board 100 will be described according to an embodiment.

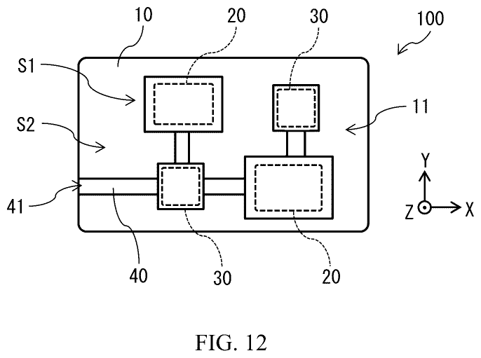

In an embodiment, the resin part 40 may have no protruding part on the side surface of the resin part 40, for example, as illustrated in FIG. 12. The protruding part may correspond to the base layer L1 having the resin thickness (the UL-certified thickness t_ul). This configuration also helps to prevent a failure in waterproofing by the resin part 40 similarly to the above-described example embodiment.

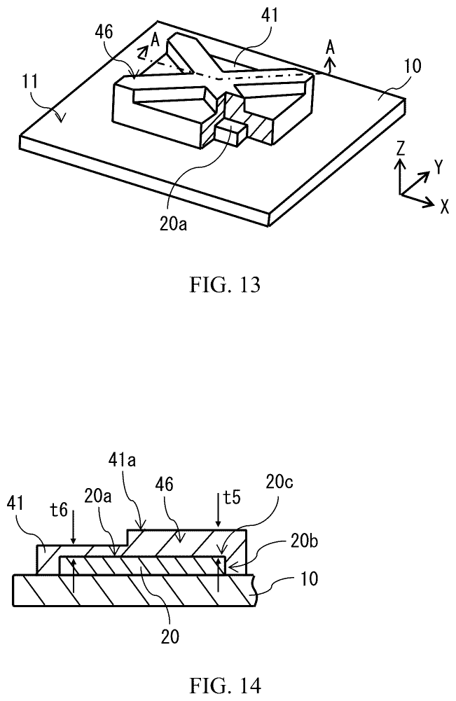

FIG. 13 illustrates a modification example of a perspective configuration of the first resin part 41. FIG. 14 illustrates a sectional configuration example of the first resin part 41 of FIG. 13 taken along line A-A. In the example embodiments and the modification example A described above, the first resin part 41 may include a radial protrusion 46 at a part opposed to the top surface 20a of the resin component 20, for example, as illustrated in FIGS. 13 and 14. The radial protrusion 46 may include a plurality of parts covering respective corner parts 20c of the top surface 20a of the resin component 20 and a part diagonally coupling the parts covering the respective corner parts 20c.

A minimum thickness of parts of the first resin part 41 covering the respective corner parts 20c of the top surface 20a of the resin component 20 may be represented by t5. The minimum thickness t5 may correspond to a minimum thickness of the first resin part 41 from each of the corner parts 20c of the top surface 20a of the resin component 20 to part of the outer surface 41a of the first resin part 41 opposed to corresponding one of the corner parts 20c. A minimum thickness of a part of the first resin part 41 covering the top surface 20a of the resin component 20 may be represented by t6. The minimum thickness t6 may correspond to a minimum thickness of the first resin part 41 from the top surface 20a of the resin component 20 to part of the outer surface 41a of the first resin part 41 opposed to the top surface 20a. In an embodiment, t5 and t6 may satisfy the following Expression (8).

t5>t6 (8)

A displacement amount of the part of the first resin part 41 covering each of the corner parts 20c of the top surface 20a of the resin component 20 when the resin component 20 expands and contracts may be the largest compared with other parts of the first resin part 41. In the present modification example, the radial protrusion 46 may be provided at the parts of the first resin part 41 where the displacement amount when the resin component 20 expands and contracts is the largest compared with other parts of the first resin part 41. Thus, the displacement of the resin component 20 is suppressed by the radial protrusion 46. As a result, the adhesion force between the first resin part 41 and the wiring substrate 10 is maintained, and therefore, entry of water between the first resin part 41 and the wiring substrate 10 is prevented. This helps to prevent a failure in waterproofing by the resin part 40.

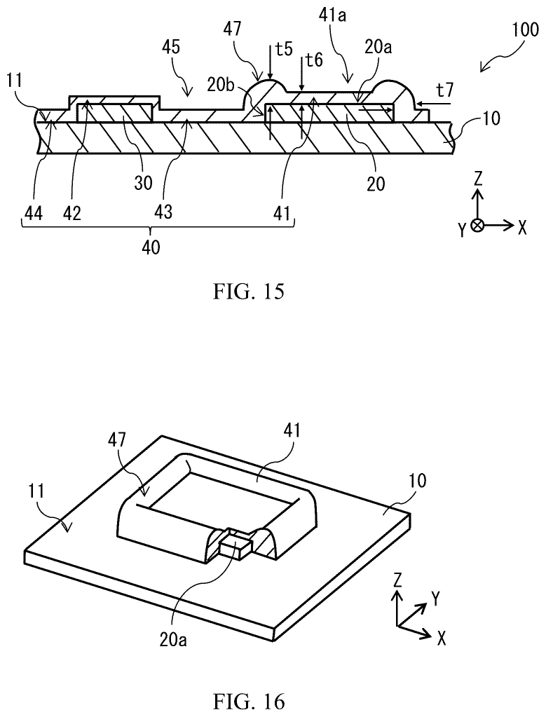

FIG. 15 illustrates a modification example of the sectional configuration example of the first resin part 41 of FIG. 1 taken along line A-A. FIG. 16 illustrates a perspective configuration example of the first resin part 41 of FIG. 15. In the example embodiments and the modification example A described above, the first resin part 41 may include, for example, as illustrated in FIGS. 15 and 16, an annular protrusion 47. The annular protrusion 47 may be a part of the first resin part 41 in contact with an edge part and the side surface 20b of the top surface 20a of the resin component 20. The annular protrusion 47 may be thicker than a part of the first resin part 41 in contact with a middle part of the top surface 20a of the resin component 20.

A minimum thickness of parts of the first resin part 41 covering the respective corner parts 20c of the top surface 20a of the resin component 20 may be represented by t5. The minimum thickness t5 may correspond to a minimum thickness of the first resin part 41 from each of the corner parts 20c of the top surface 20a of the resin component 20 to part of the outer surface 41a of the first resin part 41 opposed to the corresponding one of the corner parts 20c. A minimum thickness of a part of the first resin part 41 covering the top surface 20a of the resin component 20 may be represented by t6. The minimum thickness t6 may correspond to a minimum thickness of the first resin part 41 from the top surface 20a of the resin component 20 to part of the outer surface 41a of the first resin part 41 opposed to the top surface 20a. In an embodiment, t5 and t6 may satisfy the following Expression (8).

t5>t6 (8)

A minimum thickness of a part of the first resin part 41 covering the edge part of the top surface 20a of the resin component 20 may be represented by t5. The minimum thickness t5 may correspond to a minimum thickness of the first resin part 41 from the edge part of the top surface 20a of the resin component 20 to part of the outer surface 41a of the first resin part 41 opposed to the edge part of the top surface 20a. A minimum thickness of a part of the first resin part 41 covering the middle part of the top surface 20a of the resin component 20 may be represented by t6. The minimum thickness t6 may correspond to a minimum thickness from the middle part of the top surface 20a of the resin component 20 to part of the outer surface 41a of the first resin part 41 opposed to the middle part of the top surface 20a of the resin component 20. A minimum thickness of a part of the first resin part 41 covering the side surface 20b of the resin component 20 may be represented by t7. The minimum thickness t7 may correspond to a minimum thickness of the first resin part 41 from the side surface 20b of the resin component 20 to part of the outer surface 41a of the first resin part 41 opposed to the side surface 20b of the resin component 20. In an embodiment, t5 to t7 may satisfy the following Expressions (9) and (10).

t5>t6 (9)

t7>t6 (10)

The displacement amount of the part of the first resin part 41 covering each of the corner parts 20c of the top surface 20a of the resin component 20 when the resin component 20 expands and contracts may be the largest compared with other parts of the first resin part 41. In the present modification example, the annular protrusion 47 may be provided at the part of the first resin part 41 where the displacement amount when the resin component 20 expands and contracts is the largest compared with other parts of the first resin part 41. Thus, the displacement of the resin component 20 is suppressed by the annular protrusion 47. As a result, the adhesion force between the first resin part 41 and the wiring substrate 10 is maintained, and therefore, entry of water between the first resin part 41 and the wiring substrate 10 is prevented. This helps to prevent a failure in waterproofing by the resin part 40.

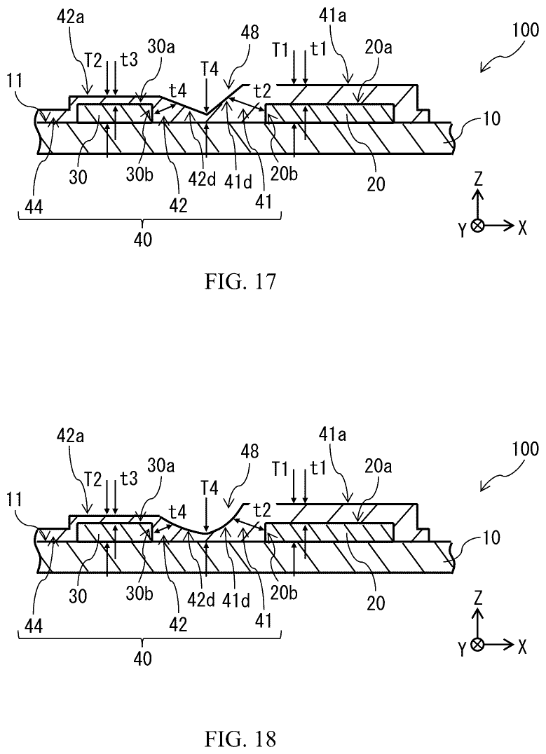

FIG. 17 illustrates a modification example of the sectional configuration example of the first resin part 41 of FIG. 1 taken along line A-A. In the example embodiments and the modification examples A to C described above, for example, as illustrated in FIG. 17, the third resin part 43 may be omitted, and the first resin part 41 and the second resin part 42 may be directly coupled to each other. In an embodiment, the resin part 40 may include a grooved part 48. The grooved part 48 may include an inner surface including a first side surface 41d and a second side surface 42d. The first side surface 41d may be a part of a surface of a region, in the outer surface 41a of the first resin part 41, covering the side surface 20b of the resin component 20. The second side surface 42d may be a part of a surface of a region, in the outer surface 42a of the second resin part 42, covering the side surface 30b of the metal component 30. A region of the grooved part 48 where the first side surface 41d and the second side surface 42d are in contact with each other may be locally thin in the resin part 40 and have a thickness T4 from the major surface 11.

The grooved part 48 may have, for example, a V-shaped section as illustrated in FIG. 17. In an embodiment, both of the first side surface 41d and the second side surface 42d may be, for example, flat inclined surfaces as illustrated in FIG. 17. In an embodiment, the grooved part 48 may have, for example, a U-shaped section as illustrated in FIG. 18. In this case, both of the first side surface 41d and the second side surface 42d may be, for example, curved inclined surfaces as illustrated in FIG. 18. In an embodiment, the thickness T4 may satisfy the following Expression (11).

T4<t1 (11)

In the present modification example, the grooved part 48 may be provided that includes the first side surface 41d of the first resin part 41 and the second side surface 42d of the second resin part 42 as the inner wall. In this case, the thickness T4 related to a depth of the grooved part 48 may satisfy Expression (11). Providing the resin part 40 with the grooved part 48 having no flat bottom surface as described above causes the stress generated in the first resin part 41 due to the expansion of the resin component 20 to be locally concentrated at a part of the grooved part 48 where the first side surface 41d and the second side surface 42d are in contact with each other. Consequently, as compared with the case where the resin part 40 is provided with the grooved part 45 having a flat bottom surface, it is more difficult for the stress generated in the first resin part 41 due to the expansion of the resin component 20 to reach the vicinity of the side surface of the metal component 30 because the stress concentration occurs in the grooved part 48. As a result, it is possible to reduce the possibility that peeling occurs in the resin part 40 (the second resin part 42) in the vicinity of the side surface of the metal component 30. This helps to prevent a failure in waterproofing by the resin part 40.

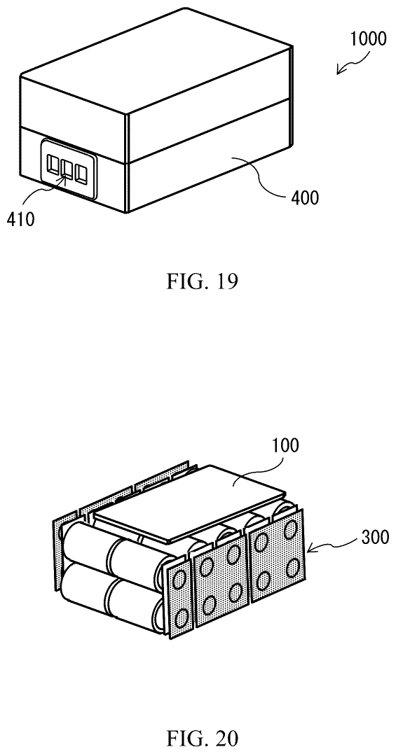

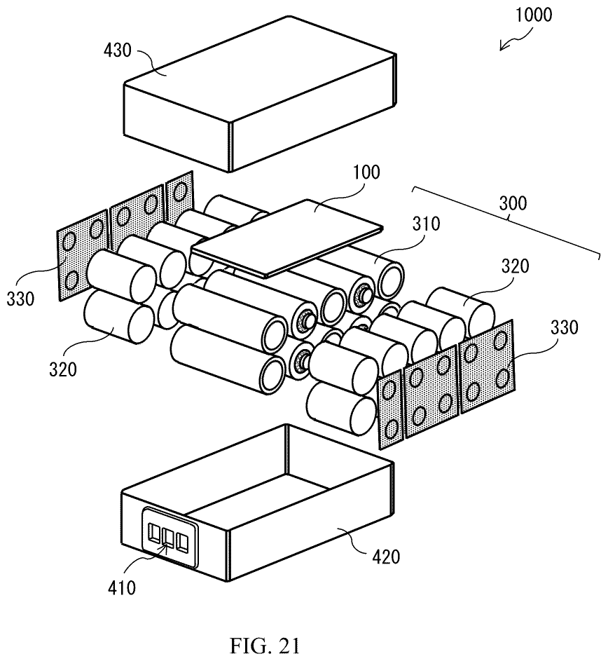

FIG. 19 illustrates a perspective configuration example of a battery pack 1000 including the circuit board 100 according to any of the example embodiments and the modification examples described above (hereinafter, simply referred to as the “circuit board 100”). FIG. 20 illustrates a perspective configuration example of a battery module 300 and the circuit board 100 that are contents of the battery pack 1000. FIG. 21 illustrates an exploded perspective configuration example of the battery pack 1000.

As illustrated in FIGS. 19 and 20, the battery pack 1000 may include, for example, an outer casing 400, and the battery module 300 and the circuit board 100, which are housed in the outer casing 400. The battery module 300 may include, for example, one or more batteries 310, a plurality of battery holders 320, and a plurality of metal tabs 330 as illustrated in FIG. 21. The circuit board 100 may be coupled to, for example, the plurality of metal tabs 330, and serve as a control board that controls charging and discharging of the one or more batteries 310. In an embodiment, the circuit board 100 may include, for example, a circuit for tasks such as measuring a voltage of the one or more batteries 310, detecting a remaining capacity of the one or more batteries 310, and detecting whether there is an overcurrent by measuring a current outputted from the one or more batteries 310.

The outer casing 400 may include, for example, a lower casing 420 and an upper casing 430 as illustrated in FIG. 21. The lower casing 420 and the upper casing 430 may be stacked on each other to form a housing space for housing the battery module 300 and the circuit board 100. The outer casing 400 (for example, the lower casing 420) may be provided with an external terminal 410 coupled to the circuit board 100. The battery module 300 may be coupled to the external terminal 410 via the circuit board 100.

In the present application example, the circuit board 100 according to any of the example embodiments and the modification examples A to D described above may be used for the battery pack 1000. This helps to prevent deterioration of the plurality of electronic components (the plurality of resin components 20 and the plurality of metal components 30) of the circuit board 100 due to, for example but not limited to, moisture in the atmosphere. It is therefore possible to provide the battery pack 1000 having high resistance to, for example but not limited to, moisture in the atmosphere.

Although the present disclosure has been described hereinabove with reference to some example embodiments and modification examples, the present disclosure is not limited to the examples described in the above-described example embodiments, and various modifications can be made to the present disclosure. The effects described herein are mere examples, and effects of the present disclosure are therefore not limited to those described herein. Accordingly, an embodiment of the present disclosure may achieve any other effect.

Furthermore, the present disclosure encompasses any possible combination of some or all of the various embodiments and the modification examples described herein and incorporated herein. It is possible to achieve at least the following configurations from the above-described example embodiments of the present disclosure.

(1)

A circuit board including:
a wiring substrate including a major surface;
a plurality of electronic components mounted on the major surface; and
a resin part covering the plurality of electronic components, in which
the plurality of electronic components includes a first component mainly including resin and a second component mainly including metal,
the resin part includes one kind of resin material,
the resin part includes a first resin part covering a surface of the first component and a second resin part covering a surface of the second component, and
t1 to t4 satisfy the following Expressions (1) to (4),

t1>t3 (1)

t1>t4 (2)

t2>t3 (3)

t2>t4 (4)
where
t1 is a maximum thickness of a part of the first resin part covering a top surface of the first component,
t2 is a maximum thickness of a part of the first resin part covering a side surface of the first component,
t3 is a maximum thickness of a part of the second resin part covering a top surface of the second component, and
t4 is a maximum thickness of a part of the second resin part covering a side surface of the second component.
   (2)

The circuit board according to (1), in which
the resin part further includes a third resin part provided between the first resin part and the second resin part, the third resin part coupling the first resin part and the second resin part, and T1 to T3 satisfy the following Expressions (5) and (6),

T3<T1 (5)

T3<T2 (6)
where
T1 is a maximum height of the first resin part from the major surface, T2 is a maximum height of the second resin part from the major surface, and T3 is a maximum height of the third resin part from the major surface.
   (3)

The circuit board according to (2), in which the resin part includes a grooved part, the grooved part includes an inner wall and a bottom surface, the inner wall includes a part of a surface of a region, in an outer surface of the first resin part, covering the side surface of the first component and a part of a surface of a region, in an outer surface of the second resin part, covering the side surface of the second component, and the bottom surface includes a surface of the third resin part.

(4)

The circuit board according to (3), in which
the maximum height T3 corresponds to a height from the major surface to the bottom surface of the grooved part and satisfies the following Expression (7),

T3<t1 (7).

(5)

The circuit board according to (1), in which the resin part includes a grooved part, the grooved part includes an inner surface including a first side surface and a second side surface, the first side surface is a part of a surface of a region, in an outer surface of the first resin part, covering the side surface of the first component, the second side surface is a part of a surface of a region, in an outer surface of the second resin part, covering the side surface of the second component, and a region of the grooved part where the first side surface and the second side surface are in contact with each other is locally thin in the resin part and has a thickness T4 from the major surface.

(6)

The circuit board according to (5), in which T4 satisfies the following Expression (11):

T4<t1 (11).

(7)

The circuit board according to any one of (1) to (6), in which
t5 and t6 satisfy the following Expression (8),

t5>t6 (8)
where
t5 is a minimum thickness of parts of the first resin part covering respective corner parts of the top surface of the first component, and
t6 is a minimum thickness of a part of the first resin part covering the top surface of the first component.
   (8)

The circuit board according to any one of (1) to (6), in which
t5 to t7 satisfy the following Expressions (9) and (10),

t5>t6 (9)

t7>t6 (10)
where
t5 is a minimum thickness of a part of the first resin part covering an edge part of the top surface of the first component,
t6 is a minimum thickness of a part of the first resin part covering a middle part of the top surface of the first component, and
t7 is a minimum thickness of a part of the first resin part covering the side surface of the first component.
   (9)

The circuit board according to any one of (1) to (6), in which the first resin part includes an annular protrusion, the annular protrusion covers an edge part of the top surface of the first component and the side surface of the first component, the annular protrusion is thicker than a part of the first resin part covering a middle part of the top surface of the first component.

(10)

The circuit board according to any one of (1) to (6), in which the first resin part includes a radial protrusion, the radial protrusion includes a plurality of parts covering respective corner parts of the top surface of the first component and a part diagonally coupling the plurality of parts covering the respective corner parts.

(11)

The circuit board according to any one of (1) to (10), in which a difference between a linear expansion coefficient of the resin part and a linear expansion coefficient of the first component is larger than a difference between the linear expansion coefficient of the resin part and a linear expansion coefficient of the second component.

(12)

The circuit board according to any one of (1) to (11), in which the resin part includes one kind of resin selected from the group consisting of polyamide, polyester, and polyurethane.

(13)

A battery pack including:
one or more batteries; and
a circuit board configured to control charging and discharging of the one or more batteries, in which
the circuit board includes the circuit board according to any one of (1) to (12).

In a circuit board according to at least one example embodiment of the present disclosure and a battery pack according to at least one example embodiment of the present disclosure, a resin part including one kind of resin material covers a first component mainly including resin and a second component mainly including metal. A thickness (the maximum thickness t1 and the maximum thickness t2) of a first resin part covering a surface of the first component and a thickness (the maximum thickness t3 and the maximum thickness t4) of a second resin part covering a surface of the second component satisfy the above Expressions (1) to (4). Thus, even in an environment in which the temperature difference is large, an expansion of the first component is suppressed by the first resin part. As a result, the adhesion force between the first resin part and a wiring substrate is maintained. This helps to prevent entry of water between the first resin part and the wiring substrate.

Although the present disclosure has been described hereinabove in terms of the example embodiment and modification examples, the present disclosure is not limited thereto. It should be appreciated that variations may be made in the described example embodiment and modification examples by those skilled in the art without departing from the scope of the present disclosure as defined by the following claims.

The limitations in the claims are to be interpreted broadly based on the language employed in the claims and not limited to examples described in this specification or during the prosecution of the application, and the examples are to be construed as non-exclusive.

As used in this specification and the appended claims, the singular forms “a,” “an,” and “the” include, especially in the context of the claims, are to be construed to cover both the singular and the plural, unless otherwise indicated herein or clearly contradicted by context.

Throughout this specification and the appended claims, unless the context requires otherwise, the terms “comprise”, “include”, “have”, and their variations are to be construed to cover the inclusion of a stated element, integer, or step but not the exclusion of any other non-stated element, integer, or step.

The use of the terms first, second, etc. do not denote any order or importance, but rather the terms first, second, etc. are used to distinguish one element from another.

The term “substantially”, “approximately”, “about”, and its variants having the similar meaning thereto are defined as being largely but not necessarily wholly what is specified as understood by one of ordinary skill in the art.

The term “disposed on/provided on/formed on” and its variants having the similar meaning thereto as used herein refer to elements disposed directly in contact with each other or indirectly by having intervening structures therebetween.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A circuit board comprising:
a wiring substrate including a major surface;
a plurality of electronic components mounted on the major surface; and
a resin part covering the plurality of electronic components, wherein
the plurality of electronic components includes a first component mainly including resin and a second component mainly including metal,
the resin part includes one kind of resin material,
the resin part includes a first resin part covering a surface of the first component and a second resin part covering a surface of the second component, and
t1 to t4 satisfy the following Expressions (1) to (4),
t1>t3 (1)
t1>t4 (2)
t2>t3 (3)
t2>t4 (4)
where
t1 is a maximum thickness of a part of the first resin part covering a top surface of the first component,
t2 is a maximum thickness of a part of the first resin part covering a side surface of the first component,
t3 is a maximum thickness of a part of the second resin part covering a top surface of the second component, and
t4 is a maximum thickness of a part of the second resin part covering a side surface of the second component.

2. The circuit board according to claim 1, wherein
the resin part further includes a third resin part provided between the first resin part and the second resin part, the third resin part coupling the first resin part and the second resin part, and
T1 to T3 satisfy the following Expressions (5) and (6),
T3<T1 (5)
T3<T2 (6)
where
T1 is a maximum height of the first resin part from the major surface,
T2 is a maximum height of the second resin part from the major surface, and
T3 is a maximum height of the third resin part from the major surface.

3. The circuit board according to claim 2, wherein the resin part includes a grooved part, the grooved part includes an inner wall and a bottom surface, the inner wall includes a part of a surface of a region, in an outer surface of the first resin part, covering the side surface of the first component and a part of a surface of a region, in an outer surface of the second resin part, covering the side surface of the second component, and the bottom surface includes a surface of the third resin part.

4. The circuit board according to claim 3, wherein
the maximum height T3 corresponds to a height from the major surface to the bottom surface of the grooved part and satisfies the following Expression (7),
T3<t1 (7).

5. The circuit board according to claim 1, wherein the resin part includes a grooved part, the grooved part includes an inner surface including a first side surface and a second side surface, the first side surface is a part of a surface of a region, in an outer surface of the first resin part, covering the side surface of the first component, the second side surface is a part of a surface of a region, in an outer surface of the second resin part, covering the side surface of the second component, and a region of the grooved part where the first side surface and the second side surface are in contact with each other is locally thin in the resin part and has a thickness T4 from the major surface.

6. The circuit board according to claim 5, wherein T4 satisfies the following Expression (11),
T4<t1 (11).

7. The circuit board according to claim 1, wherein
t5 and t6 satisfy the following Expression (8),
t5>t6 (8)
where
t5 is a minimum thickness of parts of the first resin part covering respective corner parts of the top surface of the first component, and
t6 is a minimum thickness of a part of the first resin part covering the top surface of the first component.

8. The circuit board according to claim 1, wherein
t5 to t7 satisfy the following Expressions (9) and (10),
t5>t6 (9)
t7>t6 (10)
where
t5 is a minimum thickness of a part of the first resin part covering an edge part of the top surface of the first component,
t6 is a minimum thickness of a part of the first resin part covering a middle part of the top surface of the first component, and
t7 is a minimum thickness of a part of the first resin part covering the side surface of the first component.

9. The circuit board according to claim 1, wherein the first resin part includes an annular protrusion, the annular protrusion covers an edge part of the top surface of the first component and the side surface of the first component, the annular protrusion is thicker than a part of the first resin part covering a middle part of the top surface of the first component.

10. The circuit board according to claim 1, wherein the first resin part includes a radial protrusion, the radial protrusion includes a plurality of parts covering respective corner parts of the top surface of the first component and a part diagonally coupling the plurality of parts covering the respective corner parts.

11. The circuit board according to claim 1, wherein a difference between a linear expansion coefficient of the resin part and a linear expansion coefficient of the first component is larger than a difference between the linear expansion coefficient of the resin part and a linear expansion coefficient of the second component.

12. The circuit board according to claim 1, wherein the resin part includes one kind of resin selected from the group consisting of polyamide, polyester, and polyurethane.

13. A battery pack comprising:
one or more batteries; and
a circuit board configured to control charging and discharging of the one or more batteries, wherein
the circuit board includes:
a wiring substrate including a major surface;
a plurality of electronic components mounted on the major surface; and
a resin part covering the plurality of electronic components,
the plurality of electronic components includes a first component mainly including resin and a second component mainly including metal,
the resin part includes one kind of resin material,
the resin part includes a first resin part covering a surface of the first component and a second resin part covering a surface of the second component, and
t1 to t4 satisfy the following Expressions (1) to (4),
t1>t3 (1)
t1>t4 (2)
t2>t3 (3)
t2>t4 (4)
where
t1 is a maximum thickness of a part of the first resin part covering a top surface of the first component,
t2 is a maximum thickness of a part of the first resin part covering a side surface of the first component,
t3 is a maximum thickness of a part of the second resin part covering a top surface of the second component, and
t4 is a maximum thickness of a part of the second resin part covering a side surface of the second component.
